(19) United States
(12) Patent Application Publication
(10) Pub. No.: US 2025/0283213 A1
(43) Pub. Date: Sep. 11, 2025

(54) DEPOSITION APPARATUS AND DEPOSITION METHOD USING THE SAME

(71) Applicant: Samsung Display Co., Ltd., Yongin-si (KR)

(72) Inventors: Sungmin HUCH, Yongin-si (KR); Byeongchun LEE, Yongin-si (KR)

(21) Appl. No.: 18/984,944

(22) Filed: Dec. 17, 2024

(30) Foreign Application Priority Data
Mar. 5, 2024 (KR) 10-2024-0031047

(51) Int. Cl. C23C 16/04

(52) U.S. Cl. CPC C23C 16/042

(57) ABSTRACT

A deposition apparatus includes a stage on which a substrate defining a plurality of cell areas arranged in i rows and j columns (where i and j are natural numbers) is disposed, and a mask disposed on the stage, facing the substrate, and defining a plurality of openings arranged in m rows and n columns (where m and n are natural numbers). A first distance between cell areas disposed adjacent to each other in a row direction among the plurality of cell areas is smaller than a second distance between openings disposed adjacent to each other in the row direction among the plurality of openings.

This application claims priority to Korean Patent Application No. 10-2024-0031047, filed on Mar. 5, 2024, and all the benefits accruing therefrom under 35 USC § 119, the content of which in its entirety is herein incorporated by reference.

### BACKGROUND

### 1. Field

The invention relates to a deposition apparatus, and more particularly to a deposition apparatus and a deposition method using the same.

### 2. Description of the Related Art

A display device is formed by laminating a plurality of layers such as an insulating layer, a light emitting layer, a metal layer, or the like. In order to form the plurality of layers of the display device, a deposition process of depositing various types of thin films may be performed. The deposition process may be performed by closely contacting a mask which defines an opening having the same pattern as a deposition pattern of the insulating layer, the light emitting layer, the metal layer, or the like, on a target substrate on which deposition is to be performed. The deposition pattern may be formed in an area exposed by the opening, and a shape of the deposition pattern may be controlled depending on a shape of the opening.

### SUMMARY

An embodiment provides a deposition apparatus with improved reliability.

An embodiment provides a deposition method using the deposition apparatus.

A deposition apparatus, according to an embodiment, includes a stage on which a substrate defining a plurality of cell areas arranged in i rows and j columns (where i and j are natural numbers) is disposed, and a mask disposed on the stage, facing the substrate, and defining a plurality of openings arranged in m rows and n columns (where m and n are natural numbers). A first distance between cell areas disposed adjacent to each other in a row direction among the plurality of cell areas may be smaller than a second distance between openings disposed adjacent to each other in the row direction among the plurality of openings.

In an embodiment, a difference between the first distance and the second distance may satisfy the following:

$$a = ( x / n ) * 2 , \qquad ( Equation 1 )$$

where “a” may be the difference between the first distance and the second distance, and “x” may be a difference between a first length deformed in the row direction from a first center of the substrate when deformation due to thermal expansion occurs in the substrate and a second length deformed in the row direction from a second center of the mask when deformation due to thermal expansion occurs in the mask.

In an embodiment, a third distance between cell areas disposed adjacent to each other in a column direction among the plurality of cell areas may be smaller than a fourth distance between openings disposed adjacent to each other in the column direction among the plurality of openings.

In an embodiment, a difference between the third distance and the fourth distance may satisfy the following:

$$b = ( y / m ) * 2 , \qquad ( Equation 2 )$$

where “b” may be the difference between the third distance and the fourth distance, and “y” may be a difference between a third length deformed in the column direction from a first center of the substrate when deformation due to thermal expansion occurs in the substrate and a fourth length deformed in the column direction from a second center of the mask when deformation due to thermal expansion occurs in the mask.

In an embodiment, the plurality of cell areas may correspond to the plurality of openings.

In an embodiment, the plurality of cell areas and the plurality of openings may partially overlap in a plan view.

In an embodiment, when deformation due to thermal expansion occurs in the substrate and the mask, the plurality of cell areas and the plurality of openings may overlap as a whole in a plan view.

In an embodiment, a first center of the substrate and a second center of the mask may overlap in a plan view.

In an embodiment, a coefficient of thermal expansion of the substrate may be greater than a coefficient of thermal expansion of the mask.

In an embodiment, an amount of deformation due to thermal expansion of the substrate may be greater than an amount of deformation due to thermal expansion of the mask.

In an embodiment, a deposition method includes disposing a substrate defining a plurality of cell areas arranged in i rows and j columns (where i and j are natural numbers) on a stage, and disposing a mask defining a plurality of openings arranged in m rows and n columns (where m and n are natural numbers) on the stage to face the substrate. A first distance between cell areas disposed adjacent to each other in a row direction among the plurality of cell areas may be smaller than a second distance between openings disposed adjacent to each other in the row direction among the plurality of openings.

In an embodiment, a difference between the first distance and the second distance may satisfy the following:

$$a = ( x / n ) * 2 , \qquad ( Equation 1 )$$

where “a” may be the difference between the first distance and the second distance, and “x” may be a difference between a first length deformed in the row direction from a first center of the substrate when deformation due to thermal expansion occurs in the substrate and a second length deformed in the row direction from a second center of the mask when deformation due to thermal expansion occurs in the mask.

In an embodiment, a third distance between cell areas disposed adjacent to each other in a column direction among the plurality of cell areas may be smaller than a fourth distance between openings disposed adjacent to each other in the column direction among the plurality of openings.

In an embodiment, a difference between the third distance and the fourth distance may satisfy the following:

$$b = ( y / m ) * 2 , \qquad ( Equation 2 )$$

where “b” may be the difference between the third distance and the fourth distance, and “y” may be a difference between a third length deformed in the column direction from a first center of the substrate when deformation due to thermal expansion occurs in the substrate and a fourth length deformed in the column direction from a second center of the mask when deformation due to thermal expansion occurs in the mask.

In an embodiment, the plurality of cell areas may correspond to the plurality of openings.

In an embodiment, the plurality of cell areas and the plurality of openings may partially overlap in a plan view.

In an embodiment, when deformation due to thermal expansion occurs in the substrate and the mask, the plurality of cell areas and the plurality of openings may overlap as a whole in a plan view.

In an embodiment, the substrate and the mask may be disposed so that a first center of the substrate and a second center of the mask overlap in a plan view.

In an embodiment, a coefficient of thermal expansion of the substrate may be greater than a coefficient of thermal expansion of the mask.

In an embodiment, an amount of deformation due to thermal expansion of the substrate may be greater than an amount of deformation due to thermal expansion of the mask.

According to an embodiment, in a deposition apparatus, the deposition apparatus may include a mask that defines openings corresponding to cell areas defined by a substrate. A distance between the cell areas of the substrate may be different from a distance between the openings of the mask. Accordingly, even if deformation due to thermal expansion occurs in each of the substrate and the mask at a time of performing a deposition process, the cell areas of the substrate and the openings of the mask may overlap as a whole in a plan view and may not be misaligned with each other. Accordingly, a thin film deposited on the substrate through the mask may be formed to more accurately correspond to the cell areas, and thus reliability of the deposition apparatus and the deposition process using the deposition apparatus may be improved.

### BRIEF DESCRIPTION OF THE DRAWINGS

FIG. 1 is a cross-sectional view schematically illustrating a deposition apparatus, according to an embodiment.

FIG. 2 is a perspective view illustrating the substrate and the mask illustrated in FIG. 1, according to an embodiment.

FIG. 3 is a plan view illustrating the substrate illustrated in FIG. 1, according to an embodiment.

FIG. 4 is a plan view illustrating the substrate illustrated in FIG. 1, according to an embodiment.

FIG. 5 is a plan view illustrating the mask illustrated in FIG. 1, according to an embodiment.

FIG. 6 is a plan view illustrating the mask illustrated in FIG. 1, according to an embodiment.

FIG. 7 is a plan view illustrating deformation due to thermal expansion of the substrate illustrated in FIG. 1, according to an embodiment.

FIG. 8 is a plan view illustrating deformation due to thermal expansion of the mask illustrated in FIG. 1, according to an embodiment.

FIG. 9 is a plan view illustrating a state before deformation due to thermal expansion of the substrate and the mask illustrated in FIG. 1, according to an embodiment.

FIG. 10 is a plan view illustrating a state after deformation due to thermal expansion of the substrate and the mask illustrated in FIG. 1, according to an embodiment.

FIG. 11 is a cross-sectional view schematically illustrating a display device manufactured using the deposition apparatus illustrated in FIG. 1, according to an embodiment.

### DETAILED DESCRIPTION

Hereinafter, embodiments of the invention will be described in more detail with reference to the accompanying drawings. The same reference numerals are used for the same components in the drawings, and redundant descriptions of the same components will be omitted.

It will be understood that when an element (or a region, a layer, a portion, or the like) is referred to as being related to another such as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

The term “and/or,” may include all combinations of one or more of which associated configurations may define.

It will also be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the inventive concept. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “comprise”, “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof. As used herein, being “disposed directly on” may mean that there is no additional layer, film, region, plate, or the like between a part and another part such as a layer, a film, a region, a plate, or the like. For example, being “disposed directly on” may mean that two layers or two members are disposed without using an additional member such as an adhesive member, therebetween.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

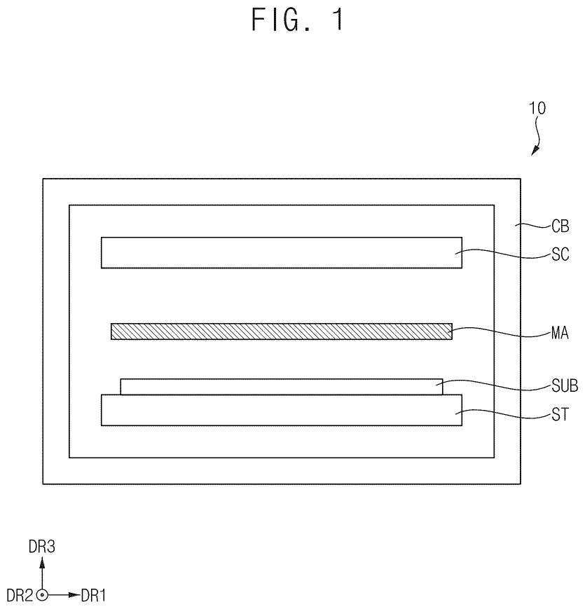

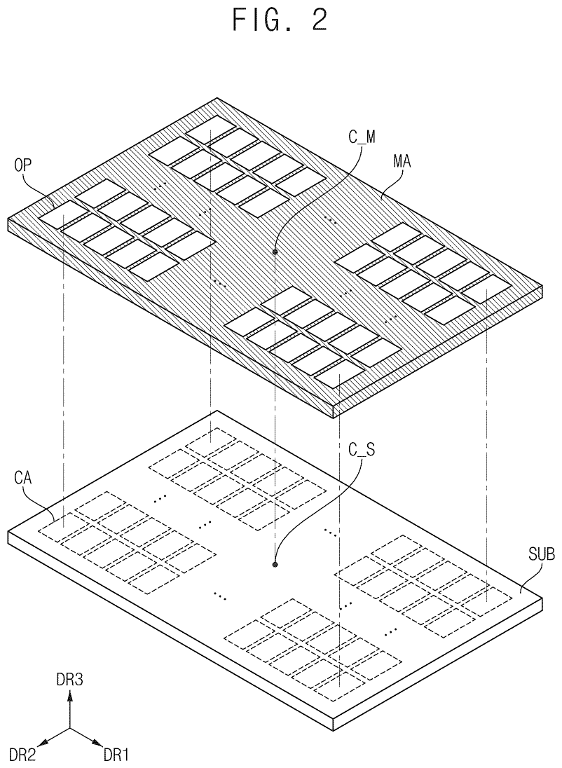

FIG. 1 is a cross-sectional view schematically illustrating a deposition apparatus, according to an embodiment. FIG. 2 is a perspective view illustrating the substrate and the mask illustrated in FIG. 1, according to an embodiment.

In an embodiment and referring to FIGS. 1 and 2, a deposition apparatus 10 may include a chamber CB, a stage ST, a deposition source SC, and a mask MA.

The deposition apparatus 10 may be used in a process of manufacturing a display device. For example, the deposition apparatus 10 may be used in a deposition process of forming a thin film on an object to be processed during the process of manufacturing the display device. In an embodiment, the object to be processed may be a substrate SUB. For example, a thin film may be formed on the substrate SUB through the deposition process using the deposition apparatus 10.

In an embodiment, the substrate SUB may refer to a mother substrate including display devices being manufactured. The substrate SUB may further include at least one layer included in the display device. For example, the substrate SUB may further include at least one of an inorganic layer, an organic layer, or a metal layer included in the display device.

In an embodiment, the deposition apparatus 10 may deposit the thin film on the substrate SUB by chemical vapor deposition (CVD). For example, the deposition apparatus 10 may perform plasma-enhanced CVD (PECVD), low pressure CVD (LPCVD), metal-organic CVD (MOCVD), or the like. The thin film may be any thin film that may be deposited by the chemical vapor deposition. For example, the thin film may be a silicon-based thin film, but the invention is not limited thereto. For example, the deposition apparatus 10 may deposit the thin film on the substrate SUB by various deposition methods, and the thin film may include various materials such as an inorganic material, an organic material, a metal, or the like.

In an embodiment, the chamber CB may provide an inner space in which a deposition process may be performed. For example, the chamber CB may be a reaction chamber including a reaction space therein. Various components that may be used in the deposition process may be disposed inside the chamber CB. During the deposition process, a temperature inside the chamber CB may be relatively high. Accordingly, heat may be applied to the components disposed inside the chamber CB during the deposition process.

In an embodiment, the stage ST may be disposed inside the chamber CB, where the stage ST may be disposed to be parallel to a plane defined by a first direction DR1 and a second direction DR2 intersecting the first direction DR1. For example, the second direction DR2 may be directed perpendicular to the first direction DR1. The substrate SUB may be disposed on the stage ST, where the stage ST may support and fix the substrate SUB.

The stage ST may be movable inside the chamber CB. For example, the stage ST may be movable up and down at a loading time point, an unloading time point, a deposition process time point, or the like. In an embodiment, the stage ST may heat and maintain the substrate SUB at a preset temperature. For example, the stage ST may include a heating member, or may be connected to a heating member. In addition, the stage ST may be connected to a power supply member to serve as an electrode.

In an embodiment, the deposition source SC may be disposed on the stage ST, where the deposition source SC may be spaced apart from the stage ST in a third direction DR3 intersecting each of the first direction DR1 and the second direction DR2. For example, the third direction DR3 may be directed perpendicular to each of the first direction DR1 and the second direction DR2. The deposition source SC may supply a deposition material into the chamber CB. In addition, the deposition source SC may be connected to a power supply member to serve as an electrode.

In an embodiment, the deposition source SC may supply gas into the chamber CB. For example, the gas may include a reaction gas, a cleaning gas, or the like. For example, when plasma is generated between the deposition source SC and the substrate SUB in the chamber CB, the reaction gas may cause a chemical reaction with an energy of the plasma to be deposited on the substrate SUB, and the cleaning gas may cause a chemical reaction with the energy of the plasma to clean the components inside the chamber CB.

In an embodiment, the mask MA may be disposed on the stage ST. For example, the mask MA may be disposed between the stage ST and the deposition source SC. The deposition material supplied from the deposition source SC may pass through the mask MA and be deposited on the substrate SUB. The mask MA may have a pattern, and the deposition material may be deposited on the substrate SUB in a pattern corresponding to the pattern of the mask MA. The mask MA may include a metal. For example, the mask MA may include an alloy of nickel (Ni) and iron (Fe). For example, the mask MA may include an invar. However, the invention is not limited thereto.

The mask MA may face the substrate SUB. For example, each of the mask MA and the substrate SUB may be disposed to be parallel to the plane defined by the first direction DR1 and the second direction DR2, and the mask MA may be disposed adjacent to the substrate SUB in the third direction DR3. In an embodiment, the mask MA may be disposed so that a first center C_S of the substrate SUB and a second center C_M of the mask MA overlap in a plan view.

In an embodiment, the mask MA may define a plurality of openings OP repeatedly arranged along the first direction DR1 and the second direction DR2. Each of the openings OP may penetrate the mask MA in a thickness direction (i.e., in the third direction DR3). The thin film may be formed on the substrate SUB in a pattern corresponding to a pattern of the openings OP, where widths of the openings OP may be determined corresponding to the pattern to be deposited.

In an embodiment, the substrate SUB may define a plurality of cell areas CA in which the thin film is deposited. A pattern of the cell areas CA may correspond to the pattern of the openings OP. The cell areas CA may be repeatedly arranged along the first direction DR1 and the second direction DR2. The cell areas CA may correspond to the openings OP. Each of the cell areas CA may correspond to a display device being manufactured.

Although FIGS. 1 and 2 illustrate that the mask MA is spaced apart from the substrate SUB by a predetermined distance, the invention is not limited thereto. For example, in another embodiment, the mask MA may be disposed to be in contact with the substrate SUB.

In addition, although FIG. 2 illustrates that the openings OP and the cell areas CA have a rectangular shape in a plan view, the invention is not limited thereto. For example, in another embodiment, the shapes of the openings OP and the cell areas CA may be variously modified depending on a shape of a display device being manufactured.

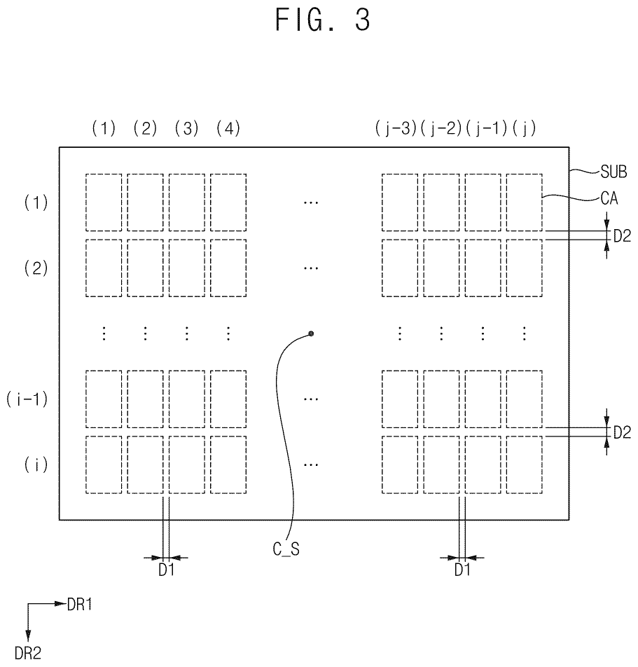

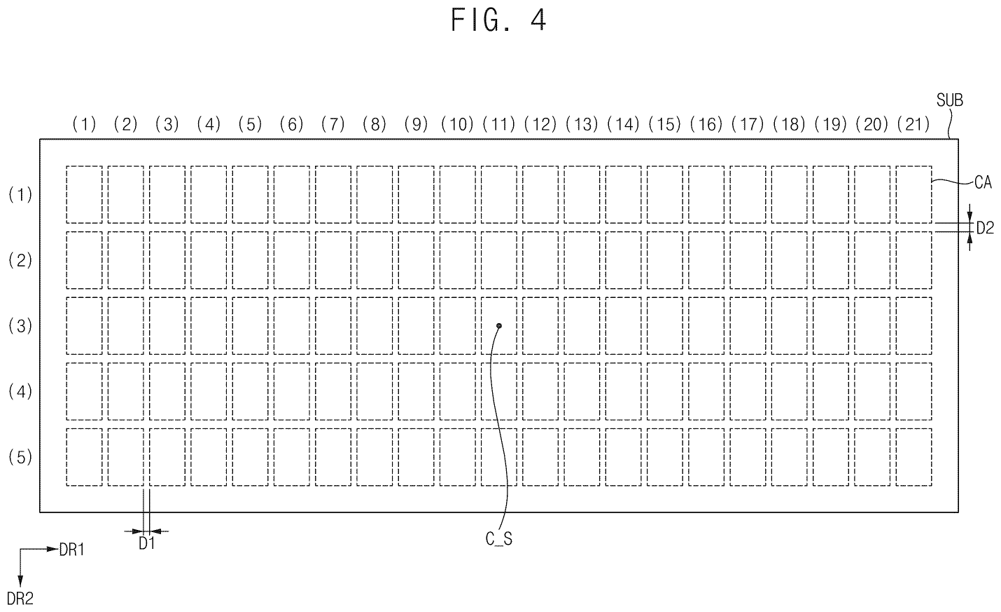

FIGS. 3 and 4 are plan views illustrating the substrate illustrated in FIG. 1, according to an embodiment. For example, FIGS. 3 and 4 may be plan views illustrating the substrate SUB before deformation due to thermal expansion occurs.

In an embodiment and referring to FIGS. 3 and 4, the substrate SUB may define the cell areas CA repeatedly arranged along the first direction DR1 and the second direction and DR2.

In an embodiment, the substrate SUB may define the cell areas CA arranged in i rows j columns (where i and j are natural numbers). That is, the substrate SUB may define j cell areas CA arranged along the first direction DR1 in each row and may define i cell areas CA arranged along the second direction DR2 in each column. The substrate SUB may define (i*j) cell areas CA.

In an embodiment, when i is an odd number, the first center C_S of the substrate SUB may be defined in the cell area CA defined in the {(i+1)/2}th row, and when i is an even number, the first center C_S of the substrate SUB may be defined between the cell area CA defined in the (i/2)th row and the cell area CA defined in the {(i/2)+1}th row. In addition, when j is an odd number, the first center C_S of the substrate SUB may be defined in the cell area CA defined in the {(j+1)/2}th column, and when j is an even number, the first center C_S of the substrate SUB may be defined between the cell area CA defined in the (j/2)th column and the cell area CA defined in the {(j/2)+1}th column.

For example, in an embodiment and referring to FIG. 4, the substrate SUB may define the cell areas CA arranged in 5 rows and 21 columns. That is, the substrate SUB may define 21 cell areas CA arranged along the first direction DR1 in each row and may define 5 cell areas CA arranged along the second direction DR2 in each column. In this case, the first center C_S of the substrate SUB may be defined as a center of the cell area CA defined in the third row and the eleventh column (see FIG. 4).

Among the cell areas CA, cell areas CA disposed adjacent to each other in the first direction DR1 may be spaced apart by a first distance D1. Among the cell areas CA, cell areas CA disposed adjacent to each other in the second direction DR2 may be spaced apart by a second distance D2. The cell areas CA may be arranged at the first distance D1 along the first direction DR1 and may be arranged at the second distance D2 along the second direction DR2.

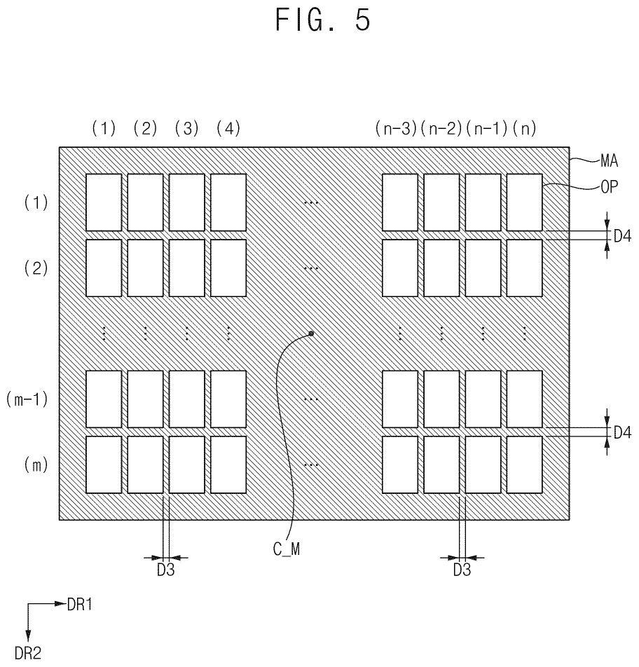

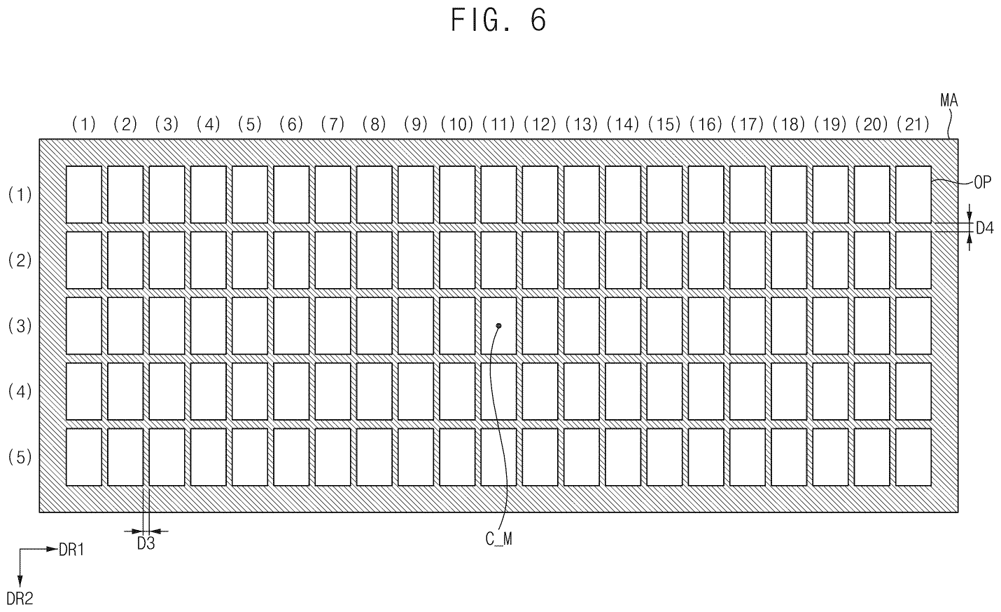

FIGS. 5 and 6 are plan views illustrating the mask illustrated in FIG. 1, according to an embodiment. For example, FIGS. 5 and 6 may be plan views illustrating the mask MA before deformation due to thermal expansion occurs.

In an embodiment and referring to FIGS. 5 and 6, the mask MA may define the openings OP repeatedly arranged along the first direction DR1 and the second direction DR2.

In an embodiment, the mask MA may define the openings OP arranged in m rows and n columns (where m and n are natural numbers). That is, the mask MA may define n openings OP arranged along the first direction DR1 in each row and may define m openings OP arranged along the second direction DR2 in each column. The mask MA may define (m*n) openings OP.

In an embodiment, i and m may be the same value, and j and n may be the same value. That is, the mask MA may define the openings OP respectively corresponding to the cell areas CA of the substrate SUB.

In an embodiment, when m is an odd number, the second center C_M of the mask MA may be defined in the opening OP defined in the {(m+1)/2}th row, and when m is an even number, the second center C_M of the mask MA may be defined between the opening OP defined in the (m/2)th row and the opening OP defined in the {(m/2)+1}th row. In addition, when n is an odd number, the second center C_M of the mask MA may be defined in the opening OP defined in the {(n+1)/2}th column, and when n is an even number, the second center C_M of the mask MA may be defined between the opening OP defined in the (n/2)th column and the opening OP defined in the {(n/2)+1}th column.

For example, referring to FIG. 6, the mask MA may define the openings OP arranged in 5 rows and 21 columns. That is, the mask MA may define 21 openings OP arranged along the first direction DR1 in each row and may define 5 openings OP arranged along the second direction DR2 in each column. In this case, the second center C_M of the mask MA may be defined as a center of the openings OP defined in the third row and the eleventh column (see FIG. 6).

In an embodiment, among the openings OP, the openings OP that are disposed adjacent to each other in the first direction DR1 may be spaced apart by a third distance D3. Among the openings OP, the openings OP that are disposed adjacent to each other in the second direction DR2 may be spaced apart by a fourth distance D4. The openings OP may be arranged from adjacent openings OP at the third distance D3 along the first direction DR1 and may be arranged from adjacent openings OP at the fourth distance D4 along the second direction DR2.

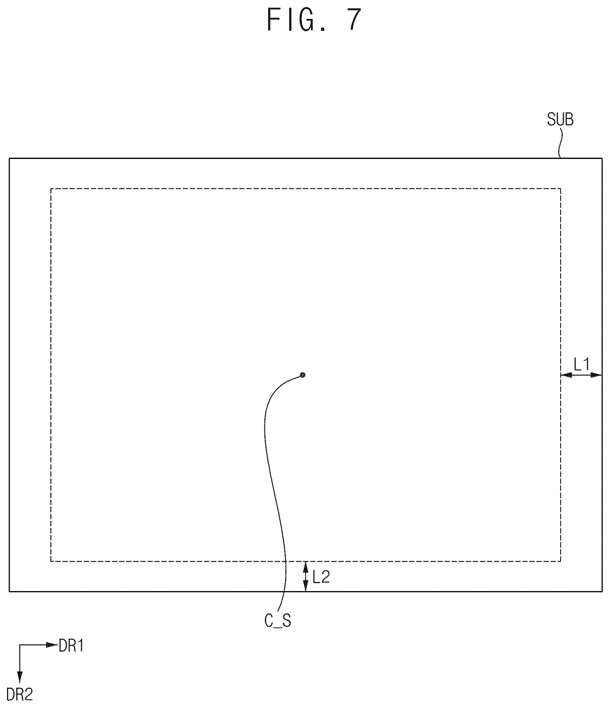

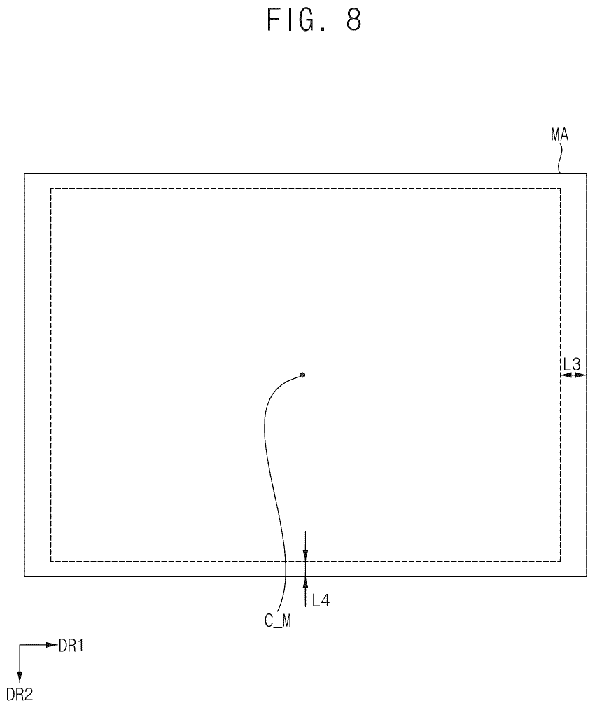

FIG. 7 is a plan view illustrating deformation due to thermal expansion of the substrate illustrated in FIG. 1, according to an embodiment. FIG. 8 is a plan view illustrating deformation due to thermal expansion of the mask illustrated in FIG. 1, according to an embodiment. For example, FIGS. 7 and 8 may be plan views illustrating the substrate SUB and the mask MA after deformation due to thermal expansion occurs.

In an embodiment and referring to FIGS. 7 and 8, each of the substrate SUB and the mask MA may be deformed by thermal expansion. For example, at a time of performing the deposition process, heat may be applied to the substrate SUB and the mask MA, and each of the substrate SUB and the mask MA may expand in the first direction DR1, a direction opposite to the first direction DR1, the second direction DR2, and a direction opposite to the second direction DR2.

In an embodiment, the substrate SUB may expand by a first length L1 in the first direction DR1 from the first center C_S of the substrate SUB, and may expand by a second length L2 in the second direction DR2 from the first center C_S of the substrate SUB.

In an embodiment, the mask MA may expand by a third length L3 in the first direction DR1 from the second center C_M of the mask MA, and may expand by a fourth length L4 in the second direction DR2 from the second center C_M of the mask MA.

In an embodiment, a thermal expansion coefficient of the substrate SUB may be greater than a thermal expansion coefficient of the mask MA. For example, since the substrate SUB and the mask MA include different materials, an amount of deformation due to thermal expansion of the substrate SUB may be greater than an amount of deformation due to thermal expansion of the mask MA.

Accordingly, when heat is applied to the substrate SUB and the mask MA, the substrate SUB may be relatively further deformed than the mask MA. That is, the first length L1 at which the substrate SUB is deformed in the first direction DR1 may be greater than the third length L3 at which the mask MA is deformed in the first direction DR1, and the second length L2 at which the substrate SUB is deformed in the second direction DR2 may be greater than the fourth length L4 at which the mask MA is deformed in the second direction DR2.

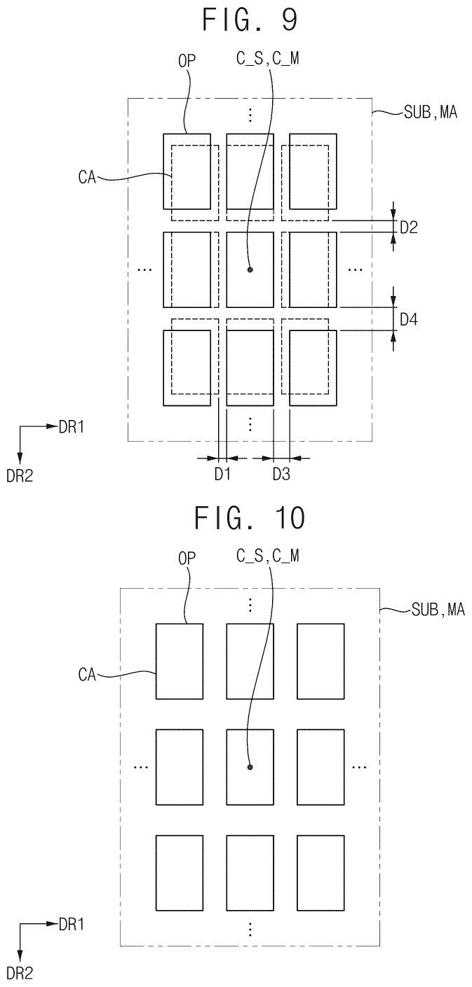

FIG. 9 is a plan view illustrating a state before deformation due to thermal expansion of the substrate and the mask illustrated in FIG. 1, according to an embodiment. FIG. 10 is a plan view illustrating a state after deformation due to thermal expansion of the substrate and the mask illustrated in FIG. 1, according to an embodiment. For example, FIGS. 9 and 10 may be plan views illustrating a peripheral part of the first center C_S of the substrate SUB and a peripheral part of the second center C_M of the mask MA.

In an embodiment and referring to FIGS. 2, 7, 8, and 9, the substrate SUB and the mask MA may be disposed to overlap in a plan view. Specifically, the substrate SUB and the mask MA may be disposed so that the first center C_S and the second center C_M overlap in a plan view.

In an embodiment, the first distance D1 between the cell areas CA disposed adjacent to each other in the first direction DR1 may be smaller than the third distance D3 between the openings OP disposed adjacent to each other in the first direction DR1. In addition, the second distance D2 between the cell areas CA disposed adjacent to each other in the second direction DR2 may be smaller than the fourth distance D4 between the openings OP disposed adjacent to each other in the second direction DR2. Accordingly, the cell areas CA and the openings OP may be misaligned in a plan view.

For example, in an embodiment, when the first center C_S of the substrate SUB and the second center C_M of the mask MA overlap in a plan view, except for the cell area CA in which the first center C_S is defined and the opening OP in which the second center C_M is defined, the cell areas CA and the openings OP may partially overlap in a plan view. That is, the cell area CA in which the first center C_S is defined may overlap the opening OP in which the second center C_M is defined as a whole in a plan view, and portions of the cell areas CA in which the first center C_S is not defined may not overlap the openings OP in which the second center C_M is not defined in a plan view.

In an embodiment, a difference between the first distance D1 and the third distance D3 may satisfy Equation 1 below, where the third distance D3 may be greater than the first distance D1 by the difference.

$$a = ( x / n ) * 2. \qquad [ Equation 1 ]$$

In Equation 1 above, “a” may be the difference between the first distance D1 and the third distance D3. In addition, “x” may be a difference between the first length L1 deformed in the first direction DR1 from the first center C_S of the substrate SUB when deformation due to thermal expansion occurs in the substrate SUB and the third length L3 deformed in the first direction DR1 from the second center C_M of the mask MA when deformation due to thermal expansion occurs in the mask MA. In addition, “n” may be a number of the openings OP that are arranged along the first direction DR1 in each row of the mask MA.

For example, in an embodiment, when the difference between the first length L1 deformed in the first direction DR1 from the first center C_S of the substrate SUB and the third length L3 deformed in the first direction DR1 from the second center C_M of the mask MA is about 70 μm (i.e., x is about 70 μm) and the mask MA defines 21 openings OP that are arranged along the first direction DR1 in each row (i.e., n is 21), the difference a between the first distance D1 and the third distance D3 may be about 6.67 μm. That is, the openings OP of the mask MA may be arranged at distances about 6.67 μm greater than the cell areas CA of the substrate SUB along the first direction DR1.

In an embodiment, a difference between the second distance D2 and the fourth distance D4 may satisfy Equation 2 below, where the fourth distance D4 may be greater than the second distance D2 by the difference.

$$b = ( y / m ) * 2. \qquad [ Equation {2}^{′} ]$$

In Equation 2 above, “b” may be the difference between the second distance D2 and the fourth distance D4. In addition, “y” may be a difference between the second length L2 deformed in the second direction DR2 from the first center C_S of the substrate SUB when deformation due to thermal expansion occurs in the substrate SUB and the fourth length L4 deformed in the second direction DR2 from the second center C_M of the mask MA when deformation due to thermal expansion occurs in the mask MA. In addition, “m” may be a number of the openings OP that are arranged along the second direction DR2 in each column of the mask MA.

For example, in an embodiment, when the difference between the second length L2 deformed in the second direction DR2 from the first center C_S of the substrate SUB and the fourth length L4 deformed in the second direction DR2 from the second center C_M of the mask MA is about 40 μm (i.e., y is about 40 μm) and the mask MA defines 5 openings OP that are arranged along the second direction DR2 in each column (i.e., m is 5), the difference b between the second distance D2 and the fourth distance D4 may be about 16 μm. That is, the openings OP of the mask MA may be arranged at distances about 16 μm greater than the cell areas CA of the substrate SUB along the second direction DR2.

In an embodiment and referring to FIGS. 2 and 7, 8, 9, and 10, deformation due to thermal expansion may occur in each of the substrate SUB and the mask MA.

In an embodiment, when the deposition process is performed, heat may be applied to the substrate SUB and the mask MA, and deformation due to thermal expansion may occur in each of the substrate SUB and the mask MA.

As the coefficient of thermal expansion of the substrate SUB is greater than the coefficient of thermal expansion of the mask MA, the amount of deformation due to thermal expansion of the substrate SUB may be greater than the amount of deformation due to thermal expansion of the mask MA.

In an embodiment, since the third distance D3 between the openings OP of the mask MA is formed to be greater than the first distance D1 between the cell areas CA of the substrate SUB by the difference a and the fourth distance D4 between the openings OP of the mask MA is formed to be greater than the second distance D2 between the cell areas CA of the substrate SUB by the difference b, the substrate SUB and the mask MA may be deformed so that the cell areas CA and the openings OP overlap as a whole in a plan view.

Thus, when deformation due to thermal expansion occurs in the substrate SUB and the mask MA at the time of performing the deposition process, the cell areas CA and the openings OP may correspond to each other in a plan view, and may not misalign with each other. Since the thin film deposited on the substrate SUB through the mask MA may be formed to more accurately correspond to the cell areas CA, a defect in which the thin film is deposited in an area where the thin film should not be deposited or the thin film is not deposited in an area where the thin film should be deposited may be prevented. That is, a defect in which the thin film is deposited in an area other than the cell areas CA, or the thin film is not deposited in the cell areas CA may be prevented. Accordingly, deposition accuracy of the thin film may be improved, reliability of the deposition process may be improved, and a display device with reduced dead space may be manufactured.

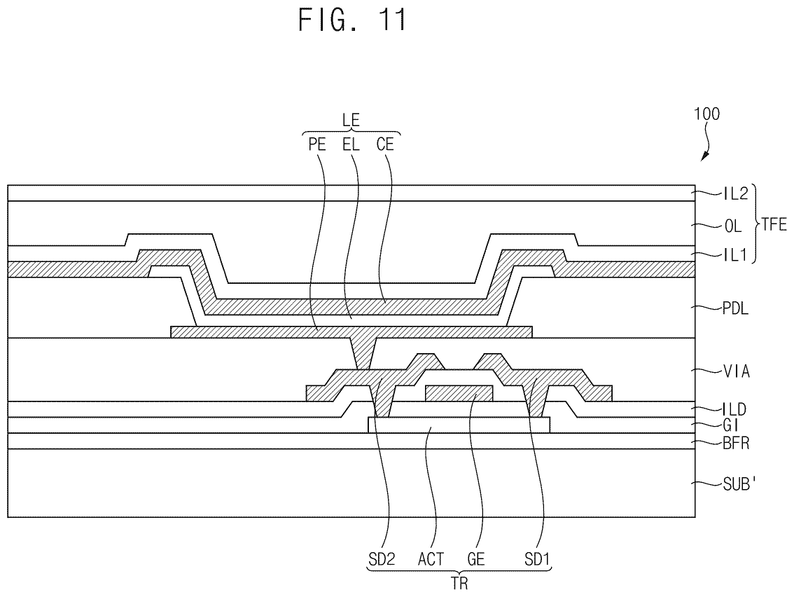

FIG. 11 is a cross-sectional view schematically illustrating a display device manufactured using the deposition apparatus illustrated in FIG. 1, according to an embodiment.

In an embodiment and referring to FIGS. 1 and 11, a display device 100 may be formed by cutting the substrate SUB into a plurality of pieces after manufacturing a plurality of display devices included in the substrate SUB.

In an embodiment, the display device 100 may include a base substrate SUB′, a buffer layer BFR, a transistor TR, a gate insulating layer GI, an interlayer insulating layer ILD, a via insulating layer VIA, a light emitting element LE, a pixel defining layer PDL, and an encapsulation layer TFE.

In an embodiment, the transistor TR may include an active pattern ACT, a gate electrode GE, a first electrode SD1, and a second electrode SD2, and the light emitting element LE may include a pixel electrode PE, a light emitting layer EL, and a common electrode CE.

In an embodiment, the base substrate SUB′ may include a transparent material or an opaque material. For example, the base substrate SUB′ may include plastic, glass, quartz, or the like. For example, the base substrate SUB′ may include polyimide. These may be used alone or in combination with each other.

In an embodiment, the buffer layer BFR may be disposed on the base substrate SUB′ and may prevent metal atoms, impurities, or the like from diffusing into the transistor TR. In addition, the buffer layer BFR may improve a flatness of a surface of the base substrate SUB′ when the surface of the base substrate SUB′ is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

In an embodiment, the active pattern ACT may be disposed on the buffer layer BFR and the active pattern ACT may include a source area, a drain area, and a channel area between the source area and the drain area. The active pattern ACT may include a silicon semiconductor material or an oxide semiconductor material. Examples of the silicon semiconductor material may include amorphous silicon, polycrystalline silicon, or the like. Examples of the oxide semiconductor material may include indium gallium zinc oxide (IGZO), indium tin zinc oxide (ITZO), or the like. These may be used alone or in combination with each other.

In an embodiment, the gate insulating layer GI may be disposed on the active pattern ACT, and may cover the active pattern ACT. The gate insulating layer GI may include an inorganic material such as silicon oxide, silicon nitride, silicon oxynitride, or the like. These may be used alone or in combination with each other.

In an embodiment, the gate electrode GE may be disposed on the gate insulating layer GI and the gate electrode GE may overlap the channel area of the active pattern ACT in a plan view. The gate electrode GE may include a metal, an alloy, a conductive metal nitride, a conductive metal oxide, a transparent conductive material, or the like. These may be used alone or in combination with each other.

In an embodiment, the interlayer insulating layer ILD may be disposed on the gate electrode GE, and may cover the gate electrode GE. The interlayer insulating layer ILD may include an inorganic material such as silicon oxide, silicon nitride, silicon oxynitride, or the like. These may be used alone or in combination with each other.

In an embodiment, the first electrode SD1 and the second electrode SD2 may be disposed on the interlayer insulating layer ILD. The first electrode SD1 may be connected to the source area of the active pattern ACT through a first contact hole penetrating the gate insulating layer GI and the interlayer insulating layer ILD. In addition, the second electrode SD2 may be connected to the drain area of the active pattern ACT through a second contact hole penetrating the gate insulating layer GI and the interlayer insulating layer ILD. For example, each of the first electrode SD1 and the second electrode SD2 may include a metal, an alloy, a conductive metal nitride, a conductive metal oxide, a transparent conductive material, or the like. These may be used alone or in combination with each other.

In an embodiment, the transistor TR including the active pattern ACT, the gate electrode GE, the first electrode SD1, and the second electrode SD2 may be disposed on the base substrate SUB′.

In an embodiment, the via insulating layer VIA may be disposed on the interlayer insulating layer ILD, and may cover the first electrode SD1 and the second electrode SD2. The via insulating layer VIA may include an organic material such as a phenol resin, an acrylic resin, a polyimide resin, a polyamide resin, a siloxane resin, an epoxy resin, or the like. These may be used alone or in combination with each other.

In an embodiment, the pixel electrode PE may be disposed on the via insulating layer VIA. The pixel electrode PE may be connected to the second electrode SD2 through a contact hole penetrating the via insulating layer VIA. The pixel electrode PE may include a metal, an alloy, a conductive metal nitride, a conductive metal oxide, a transparent conductive material, or the like. These may be used alone or in combination with each other. For example, the pixel electrode PE may operate as an anode.

In an embodiment, the pixel defining layer PDL may be disposed on the via insulating layer VIA, and may cover at least a portion of the pixel electrode PE. An opening exposing at least a portion of an upper surface of the pixel electrode PE may be defined in the pixel defining layer PDL. The pixel defining layer PDL may include an inorganic material or an organic material. For example, the pixel defining layer PDL may include an organic material such as an epoxy resin, a siloxane resin, or the like. In another embodiment, the pixel defining layer PDL may include an inorganic material or an organic material including a light blocking material having a black color.

In an embodiment, the light emitting layer EL may be disposed on the pixel electrode PE. The light emitting layer EL may be disposed on the pixel electrode PE exposed by the pixel defining layer PDL. The light emitting layer EL may include an organic material that emits light of a predetermined color.

In an embodiment, the common electrode CE may be disposed on the light emitting layer EL, where the common electrode CE may be a plate electrode. The common electrode CE may include a metal, an alloy, a conductive metal nitride, a conductive metal oxide, a transparent conductive material, or the like. These may be used alone or in combination with each other. For example, in an embodiment, the common electrode CE may operate as a cathode.

In an embodiment, the light emitting element LE including the pixel electrode PE, the light emitting layer EL, and the common electrode CE may be disposed on the base substrate SUB′. The light emitting element LE may be electrically connected to the transistor TR.

In an embodiment, the encapsulation layer TFE may be disposed on the common electrode CE, where the encapsulation layer TFE may protect the light emitting element LE from external oxygen, moisture, or the like. The encapsulation layer TFE may include at least one inorganic layer and at least one organic layer. For example, the encapsulation layer TFE may have a structure in which inorganic layers and organic layers are alternately stacked.

In an embodiment, the encapsulation layer TFE may include a first inorganic layer IL1, an organic layer OL disposed on the first inorganic layer IL1, and a second inorganic layer IL2 disposed on the organic layer OL. The first inorganic layer IL1 and the second inorganic layer IL2 may include an inorganic material such as silicon oxide, silicon nitride, silicon oxynitride, or the like. These may be used alone or in combination with each other. The organic layer OL may include an organic material such as an acrylic resin, a polyimide resin, an epoxy resin, or the like. These may be used alone or in combination with each other.

In an embodiment, the first inorganic layer IL1 and the second inorganic layer IL2 may be formed by using the deposition apparatus 10. For example, as the substrate SUB on which the common electrode CE is formed passes through the deposition apparatus 10, the first inorganic layer IL1 and the second inorganic layer IL2 may be formed.

However, the invention is not limited thereto, and various insulating layers included in the display device 100, such as the buffer layer BFR, the gate insulating layer GI, the interlayer insulating layer ILD, or the like, may be formed by using the deposition apparatus 10. In addition, various thin films included in the display device 100, such as the active pattern ACT, the gate electrode GE, the first electrode SD1, the second electrode SD2, the pixel electrode PE, the light emitting layer EL, the common electrode CE, or the like, may be formed by using the deposition apparatus 10.

In an embodiment, the deposition apparatus 10 may include the mask MA defining the openings OP that respectively correspond to the cell areas CA defined by the substrate SUB. The first and second distances D1 and D2 between the cell areas CA of the substrate SUB may be different from the third and fourth distances D3 and D4 between the openings OP of the mask MA, respectively. Accordingly, even if deformation due to thermal expansion occurs in each of the substrate SUB and the mask MA at the time of performing the deposition process, the cell areas CA of the substrate SUB and the openings OP of the mask MA may overlap each other as a whole in a plan view and may not be misaligned with each other. Therefore, the thin film deposited on the substrate SUB by passing through the mask MA may be formed to more accurately correspond to the cell areas CA, and thus reliability of the deposition apparatus 10 and the deposition process using the deposition apparatus 10 may be improved.

The invention can be applied to a manufacturing process of various display devices. For example, the invention is applicable to a manufacturing process of various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without departing from the novel teachings and advantages of the invention. Accordingly, all such modifications are intended to be included within the scope of the invention. Therefore, it is to be understood that the foregoing is illustrative of various embodiments and is not to be construed as limited to the specific embodiments disclosed, and that modifications to the disclosed embodiments, as well as other embodiments, are intended to be included within the scope of the invention. Moreover, the embodiments or parts of the embodiments may be combined in whole or in part without departing from the scope of the invention.

What is claimed is:

1. A deposition apparatus comprising:
a stage on which a substrate defining a plurality of cell areas arranged in i rows and j columns is disposed, wherein i and j are natural numbers; and
a mask disposed on the stage, facing the substrate, and defining a plurality of openings arranged in m rows and n columns, wherein m and n are natural numbers, and
wherein a first distance between cell areas disposed adjacent to each other in a row direction among the plurality of cell areas is smaller than a second distance between openings disposed adjacent to each other in the row direction among the plurality of openings.

2. The deposition apparatus of claim 1, wherein a difference between the first distance and the second distance satisfies:
$$a = ( x / n ) * 2 , \qquad ( Equation 1 )$$
wherein a is the difference between the first distance and the second distance, and x is a difference between a first length deformed in the row direction from a first center of the substrate when deformation due to thermal expansion occurs in the substrate and a second length deformed in the row direction from a second center of the mask when deformation due to thermal expansion occurs in the mask.

3. The deposition apparatus of claim 1, wherein a third distance between cell areas disposed adjacent to each other in a column direction among the plurality of cell areas is smaller than a fourth distance between openings disposed adjacent to each other in the column direction among the plurality of openings.

4. The deposition apparatus of claim 3, wherein a difference between the third distance and the fourth distance satisfies:
$$b = ( y / m ) * 2 , \qquad ( Equation 2 )$$
wherein b is the difference between the third distance and the fourth distance, and y is a difference between a third length deformed in the column direction from a first center of the substrate when deformation due to thermal expansion occurs in the substrate and a fourth length deformed in the column direction from a second center of the mask when deformation due to thermal expansion occurs in the mask.

5. The deposition apparatus of claim 1, wherein the plurality of cell areas correspond to the plurality of openings.

6. The deposition apparatus of claim 5, wherein the plurality of cell areas and the plurality of openings partially overlap in a plan view.

7. The deposition apparatus of claim 5, wherein when deformation due to thermal expansion occurs in the substrate and the mask, the plurality of cell areas and the plurality of openings overlap as a whole in a plan view.

8. The deposition apparatus of claim 1, wherein a first center of the substrate and a second center of the mask overlap in a plan view.

9. The deposition apparatus of claim 1, wherein a coefficient of thermal expansion of the substrate is greater than a coefficient of thermal expansion of the mask.

10. The deposition apparatus of claim 9, wherein an amount of deformation due to thermal expansion of the substrate is greater than an amount of deformation due to thermal expansion of the mask.

11. A deposition method comprising:
disposing a substrate defining a plurality of cell areas arranged in i rows and j columns on a stage, wherein i and j are natural numbers; and
disposing a mask defining a plurality of openings arranged in m rows and n columns on the stage to face the substrate, wherein m and n are natural numbers, and
wherein a first distance between cell areas disposed adjacent to each other in a row direction among the plurality of cell areas is smaller than a second distance between openings disposed adjacent to each other in the row direction among the plurality of openings.

12. The deposition method of claim 11, wherein a difference between the first distance and the second distance satisfies:
$$a = ( x / n ) * 2 , \qquad ( Equation 1 )$$
wherein a is the difference between the first distance and the second distance, and x is a difference between a first length deformed in the row direction from a first center of the substrate when deformation due to thermal expansion occurs in the substrate and a second length deformed in the row direction from a second center of the mask when deformation due to thermal expansion occurs in the mask.

13. The deposition method of claim 11, wherein a third distance between cell areas disposed adjacent to each other in a column direction among the plurality of cell areas is smaller than a fourth distance between openings disposed adjacent to each other in the column direction among the plurality of openings.

14. The deposition method of claim 13, wherein a difference between the third distance and the fourth distance satisfies:
$$b = ( y / m ) * 2 , \qquad ( Equation 2 )$$
wherein b is the difference between the third distance and the fourth distance, and y is a difference between a third length deformed in the column direction from a first center of the substrate when deformation due to thermal expansion occurs in the substrate and a fourth length deformed in the column direction from a second center of the mask when deformation due to thermal expansion occurs in the mask.

15. The deposition method of claim 11, wherein the plurality of cell areas correspond to the plurality of openings.

16. The deposition method of claim 15, wherein the plurality of cell areas and the plurality of openings partially overlap in a plan view.

17. The deposition method of claim 15, wherein when deformation due to thermal expansion occurs in the substrate and the mask, the plurality of cell areas and the plurality of openings overlap as a whole in a plan view.

18. The deposition method of claim 11, wherein the substrate and the mask are disposed so that a first center of the substrate and a second center of the mask overlap in a plan view.

19. The deposition method of claim 11, wherein a coefficient of thermal expansion of the substrate is greater than a coefficient of thermal expansion of the mask.

20. The deposition method of claim 19, wherein an amount of deformation due to thermal expansion of the substrate is greater than an amount of deformation due to thermal expansion of the mask.
